(19) United States
(12) Patent Application Publication
(10) Pub. No.: US 2022/0187996 A1
(43) Pub. Date: Jun. 16, 2022

(54) MEMORY CONTROLLER AND STORAGE DEVICE INCLUDING SAME

(71) Applicant: SK hynix Inc., Gyeonggi-do (KR)

(72) Inventors: Ki Sung KIM, Gyeonggi-do (KR); Jae Hun KIM, Gyeonggi-do (KR); Seung Geol BAEK, Gyeonggi-do (KR); Dong Kyu LEE, Gyeonggi-do (KR)

(21) Appl. No.: 17/355,559

(22) Filed: Jun. 23, 2021

(30) Foreign Application Priority Data
Dec. 14, 2020 (KR) 10-2020-0174348

(51) Int. Cl. G06F 3/06

(52) U.S. Cl. CPC G06F 3/0619; G06F 3/0679; G06F 3/0653

(57) ABSTRACT

The present disclosure relates to an electronic device, and more particularly, to a memory controller and a storage device including the same. According to an embodiment, a memory controller includes a storage configured to store first defect information corresponding to a non-repairable defect and second defect information corresponding to a repairable defect, an output circuit configured to detect a defect in the memory controller and to output the first or second defect information as defect information corresponding to a detected defect, and logic configured to check a type of the detected defect based on the second defect information when the defect information corresponds to the second defect information and to perform a recovery operation according to the type of the detected defect.

### CROSS-REFERENCE TO RELATED APPLICATION

The present application claims priority under 35 U.S.C. § 119(a) to Korean patent application number 10-2020-0174348, filed on Dec. 14, 2020, in the Korean Intellectual Property Office, the entire disclosure of which is incorporated by reference herein.

### BACKGROUND

### 1. Technical Field

One or more embodiments described here relate to a memory controller and a storage device including a memory controller.

### 2. Related Art

A storage device may include a memory controller that controls the storage of data in a memory device.

A volatile memory stores data only when powered. When power is interrupted, the data is lost. Examples of the volatile memory may include Static Random Access Memory (SRAM) and Dynamic Random Access Memory (DRAM).

A non-volatile memory storage data even in the absence of the power. Examples of a non-volatile memory include Read Only Memory (ROM), Programmable ROM (PROM), Electrically Programmable ROM (EPROM), Electrically Erasable and Programmable ROM (EEPROM), and Flash Memory.

### SUMMARY

One or more embodiments described herein provide a memory controller having improved reliability.

One or more embodiments described herein provide a storage device including a memory controller having improved reliability.

According to an embodiment, a memory controller may include a storage configured to store first defect information corresponding to a non-repairable defect and second defect information corresponding to a repairable defect, an output circuit configured to detect a defect in the memory controller and to output the first or second defect information as defect information corresponding to a detected defect, and logic configured to check a type of the detected defect based on the second defect information when the defect information corresponds to the second defect information and to perform a recovery operation according to the type of the detected defect.

According to an embodiment, a storage device may include a memory device including a plurality of memory blocks, a buffer memory configured to temporarily store data from a host or the memory device, and a memory controller configured to control the memory device to perform an operation corresponding to a request from the host, wherein the memory controller is configured to: detect a defect occurring in the memory controller or the buffer memory, check whether or not the defect is reparable based on information in a defect information table, and perform a recovery operation according to a type of the defect when the defect is reparable.

According to an embodiment, An apparatus may include a storage configured to store instructions, and logic configured to execute the instructions to: detect a defect occurring in a memory controller or a buffer memory, check whether or not the defect is reparable based on a defect information table, and perform a recovery operation based on a type of the defect when the defect is reparable.

### BRIEF DESCRIPTION OF THE DRAWINGS

FIG. 1 illustrates an embodiment of a storage system;

FIG. 2 illustrates an embodiment of a memory device;

FIG. 3 illustrates an embodiment of a memory block;

FIG. 4 illustrates an example of defect information;

FIG. 5 illustrates an embodiment of a method of performing a recovery operation;

FIG. 6 illustrates an embodiment of a method of loading firmware data;

FIG. 7 illustrates an embodiment of a memory controller;

FIG. 8 illustrates an embodiment of a memory card system;

FIG. 9 illustrates an embodiment of a solid state drive (SSD) system; and

FIG. 10 illustrates an embodiment of a user system.

### DETAILED DESCRIPTION

Specific structural or functional descriptions of examples of embodiments in accordance with concepts which are disclosed in this specification are illustrated only to describe the examples of embodiments in accordance with the concepts and the examples of embodiments in accordance with the concepts may be carried out by various forms but the descriptions are not limited to the examples of embodiments described in this specification.

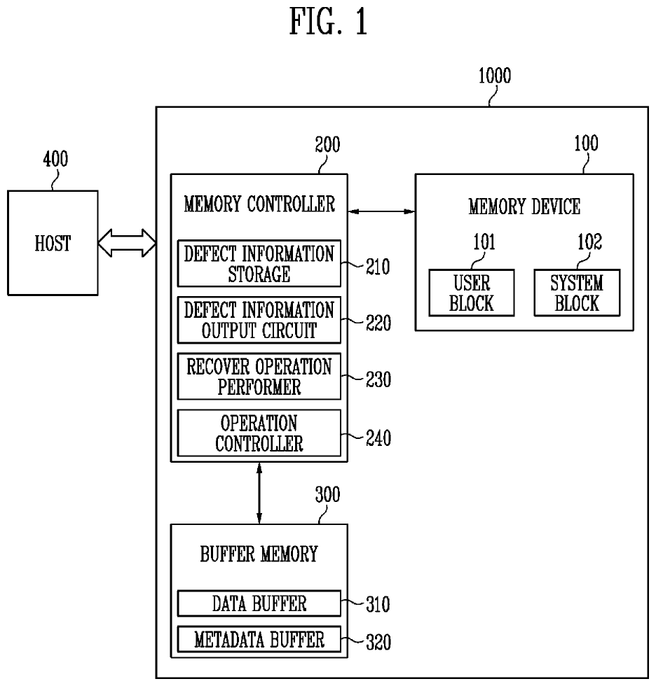

FIG. 1 is a diagram illustrating an embodiment of a storage system, which, for example, may be embodied in a personal computer (PC), a data center, an enterprise data storage system, a data processing system including a direct attached storage (DAS), a data processing system including a storage area network (SAN), or a data processing system including a network attached storage (NAS).

The storage system may include a storage device 1000 and a host 400. The storage device 1000 may be configured to store data in response to control of the host 400. Examples of the storage device 1000 include a cellular phone, a smartphone, an MP3 player, a laptop computer, a desktop computer, a game player, a TV, a tablet PC, or an in-vehicle infotainment system.

The storage device 1000 may be one of various types of storage devices according, for example, to a host interface implementing a communication method of the host 400. Examples of the storage device 1000 include a solid state drive (SSD), a multimedia card in the form of an MMC, an eMMC, an RS-MMC and a micro-MMC, a secure digital card in the form of an SD, a mini-SD and a micro-SD, a universal serial bus (USB) storage device, a universal flash storage (UFS) device, a Personal Computer Memory Card International Association (PCMCIA) card type storage device, a peripheral component interconnection (PCI) card type storage device, a PCI express (PCI-E) card type storage device, a compact flash (CF) card, a smart media card, and a memory stick.

The storage device 1000 may be embodied in various types of packages. Examples include a package-on-package (POP), a system-in-package (SIP), a system-on-chip (SOC), a multi-chip package (MCP), a chip-on-board (COB), a wafer-level fabricated package (WFP), and a wafer-level stack package (WSP).

According to an embodiment, as shown in FIG. 1, there may be one storage device 1000. In one embodiment, the storage system may include two or more storage devices 1000. The storage devices 1000 may operate, for example, as redundant array of independent disks or redundant array of inexpensive disks (RAID), in which the storage devices 1000 operate logically as a single storage device.

The storage device 1000 may include a memory device 100, a memory controller 200 and a buffer memory 300. The memory device 100 may operate in response to control of the memory controller 200. For example, the memory device 100 may receive commands and addresses from the memory controller and may access memory cells selected by the addresses from among memory cells. The memory device 100 may perform operations instructed by commands on the memory cell selected by corresponding ones of the addresses.

The commands may include, for example, a program command, a read command, and/or an erase command. The operations instructed by the commands may include, for example, a program operation (or a write operation), a read operation, or an erase operation.

A program operation may store data from host 400 in response to control of the memory controller 200. For example, memory device 100 may receive a program command, an address and data and may program data into a memory cell selected by the address. Data to be programmed to the selected memory cell may be defined as write data. The write data may include data from the host 400 (or user data) and metadata of the data.

A read operation may read data stored in the memory device 100 in response to control of the memory controller 200. For example, memory device 100 may receive a read command and an address and may read data from an area selected by the address. Data to be read from the selected area, among the data stored in the memory device 100, may be defined as read data.

An erase operation may erase data stored in the memory device 100 in response to control of the memory controller 200. For example, the memory device 100 may receive an erase command and an address, and may erase data stored in the area selected by the address.

The memory device 100 may be a volatile memory or a non-volatile memory. Examples of a volatile memory device include Double Data Rate Synchronous Dynamic Random Access Memory (DDR SDRAM), Low Power Double Data Rate4 (LPDDR4) SDRAM, Graphics Double Data Rate (GDDR) SDRAM, Low Power DDR (LPDDR), and Rambus Dynamic Random Access Memory (RDRAM). Examples of the non-volatile memory include resistive random access memory (RRAM), phase-change random access memory (PRAM), magnetoresistive random access memory (MRAM), ferroelectric random access memory (FRAM), spin transfer torque random access memory (STT-RAM), and flash memory. Flash memory may include, for example, NAND flash memory, Vertical NAND flash memory, and NOR flash memory. For convenience of explanation, it is assumed that the memory device 100 is NAND flash memory.

In response to control of the memory controller 200, the memory device 100 may store the write data, or may read the stored read data and provide the read data to the memory controller 200.

The memory device 100 may include at least one plane. Each plane may include a memory cell array that includes memory cells storing write data. The memory cell array may include a plurality of memory blocks, with each memory block being a unit for performing an erase operation to erase data.

The memory blocks may include user blocks 101 and/or system blocks 102. For example, some of the memory blocks may be the user blocks 101 and other memory blocks may be system blocks 102. A user block 101 may store data, which, for example, may be user data provided from the host 400. There may be one or more user blocks 101.

A system block 102 may store metadata, and in one or more embodiments may also refer to a memory block that stores firmware data. There may one or more system blocks 102. The metadata may indicate information about data stored in one or more of the memory blocks. For example, the metadata may include map data and valid data, and/or may include other types of data. In one embodiment, the map data may indicate a mapping relationship between a logical address and a physical address. The valid data may indicate validity of the user data from the host 400. The firmware data may be related to firmware performed by the memory controller 200.

A memory block may include a plurality of pages. A page may be a unit for performing a program operation of storing write data or a read operation of reading the stored read data.

Each memory cell may be one of a single level cell (SLC) that stores 1 bit of data, a multi-level cell (MLC) that stores 2 bits of data, a triple-level cell (TLC) that stores 3 bits of data, and a quadruple level cell (QLC) that stores 4 bits of data. In one embodiment, each memory cell may store 5 or more bits of data.

According to an embodiment, the memory device 100 may perform an operation instructed by a command according, for example, to a plane interleaving scheme. In one embodiment of a plane interleaving scheme, operations on two or more planes may at least partially overlap each other.

The memory controller 200 may control overall operation of the memory device 100. When power is applied to the storage device 1000, the memory controller 200 may execute firmware.

When the memory device 100 is a flash memory device, the firmware may include a host interface layer, a flash translation layer and a flash interface layer. The power may be supplied from an external device. The host interface layer may control operations between the host 400 and the memory controller 200. The flash translation layer may translate a logical address provided from the host 400 to a physical address. The flash interface layer may control communication between the memory controller 200 and the memory device 100.

The memory controller 200 may control the memory device 100 to perform an operation corresponding to a request from the host 400. For example, the memory controller 200 may control the memory device 100 to perform a program operation, a read operation and an erase operation in response to a write request, a read request and an erase request, respectively, from the host 400.

During a program operation, the memory controller 200 may provide a program command, a physical address and write data to the memory device 100. According to an embodiment, during a program operation, the memory controller 200 may provide a program command and a physical address to the memory device 100. In addition, the memory controller 200 may provide a flush command to the buffer memory 300 so as to provide (or flush) data temporarily stored in the buffer memory 300 to the memory device 100. When the data temporarily stored in the buffer memory 300 is provided to the memory device 100, the data temporarily stored in the buffer memory 300 may be erased.

During a read operation, the memory controller 200 may provide a read command and a physical block address to the memory device 100.

During an erase operation, the memory controller 200 may provide an erase command and a physical address to the memory device 100.

In one embodiment, the memory controller 200 may generate a command, an address and data regardless (or without) of a request from the host 400. The memory controller 200 may transfer the command, address and data generated by the memory controller 200 to the memory device 100.

The memory controller 200 may, for example, generate a command, an address and data for performing a background operation, and then provide the command, address, and data to the memory device 100. The command for performing a background operation may be, for example, a program command or a read command.

A background operation may be at least one of wear leveling, read reclaim and garbage collection. Wear leveling may refer to, for example, static wear leveling, dynamic wear leveling, or the like. Static wear leveling may refer to storing erase counts of memory blocks and moving cold data with which an erase operation or a write operation is seldom performed (e.g., less than a predetermined number of times) to a memory block with the highest erase count. Dynamic wear leveling may refer to storing erase counts of memory blocks and programming data into a memory block with the lowest erase count.

Read reclaim may refer to moving data stored in a memory block to another memory block before an uncorrectable error occurs in the data stored in the memory block.

Garbage collection may include copying valid data included in a bad block, among memory blocks, to a free block, and erasing invalid data in the bad block. Copying the valid data in the bad block may include moving the valid data included in the bad block to the free block.

The memory controller 200 may control at least two memory devices 100. To improve operating performance, the memory controller 200 may control the memory devices 100, for example, according to an interleaving scheme. According to the interleaving scheme, operations on at least two memory devices 100 may be controlled to overlap each other.

According to an embodiment, the memory controller 200 may detect a defect that has occurred in the storage device 1000, e.g., in memory device 100, in memory controller 200, and/or in buffer memory 300. According to an embodiment, when a defect is detected, the memory controller 200 may check whether the defect is repairable or not. This check may be performed, for example, based on information in a defect information table stored beforehand.

The defect information table may include information corresponding to a defect that may occur in storage device 1000. Defects that occur in the storage device 1000 may be repairable or non-repairable. A non-repairable defect may include, for example, damage to hardware in the storage device 1000. A repairable defect may include, for example, an unexpected operation performed by the firmware in the memory controller 200. Different types of repairable and non-repairable defects may occur in other embodiments.

When a defect is repairable, the memory controller 200 may check a type of the repairable defect and perform a recovery operation according to the type of the defect. Types of repairable defects include, for example, a first type and a second type. The first type may indicate a repairable defect while the memory controller 200 maintains connection with the host 400. The second type may refer to a defect which is repairable by rebooting the storage device 1000 or one based on a rebooting command from the host 400.

According to an embodiment, when the detected defect is the first type, the memory controller 200 may resume an operation being performed prior to the occurrence of the defect after the recovery operation is completed. For example, the memory controller 200 may maintain communication with the host 400 and resume the operation being performed prior to the occurrence of the defect after the recovery operation is completed.

According to an embodiment, when the detected defect is the second type, the memory controller 200 may provide the host 400 with a defect occurrence response to notify that the defect has occurred before the recovery operation is performed.

According to an embodiment, when the detected defect is the second type, the memory controller 200 may wait until the external power supply to the storage device 1000 is blocked after the recovery operation is completed. When the power is supplied again after the interruption, the memory controller 200 may resume the operation being performed prior to the occurrence of the defect.

According to an embodiment, when the detected defect is the second type, the memory controller 200 may provide the host 400 with a rebooting response to notify that a rebooting command is to be provided after the recovery operation is completed. The memory controller 200 may wait until the memory controller 200 receives the rebooting command after the rebooting response is provided to the host 400. When the host 400 provides the rebooting command to the storage device 1000, the memory controller 200 may perform a rebooting operation.

According to an embodiment, when the detected defect is the second type, the memory controller 200 may reboot after the recovery operation is completed. For example, the memory controller 200 may perform a rebooting operation regardless of (e.g., without receiving) a rebooting command from the host 400.

The memory controller 200 may include a defect information storage 210, a defect information output circuit 220, a recovery operation performer (or logic) 230, and an operation controller 240. The defect information storage 210 may store defect information indicating, for example, a defect. In one embodiment, the defect information may include first defect information corresponding to a non-repairable defect and second defect information corresponding to a repairable defect. The defect information may further information about types of defects. One type of a defect may be expressed as, for example, a code number, but may be expressed based on other types of information.

The defect information 220 may detect or be indicative of a defect. The defect may occur, for example, in the memory device 100, the memory controller 200, or the buffer memory 300. The defect information output circuit 220 may output defect information corresponding to the detected defect using the defect information stored in the defect information storage 210. For example, the defect information output circuit 220 may output the first defect information or the second defect information on the basis of defect information corresponding to the detected defect.

When the defect information provided by the defect information output circuit 220 is the second defect information, the recovery operation performer 230 may check the type of the defect detected based on (or indicated by) the second defect information and may perform a recovery operation according to the type of the detected defect.

The operation controller 240 may store a command to perform an operation corresponding to a request from the host 400 in a command queue. The operation controller 240 may provide the memory device 100 with one or more commands stored in the command queue. The command(s) may be a program command, a read command, or an erase command.

According to an embodiment, when the recovery operation starts, the recovery operation performer 230 may provide the operation controller 240 with a notification signal to stop outputting the commands stored in the command queue. The operation controller 240 may stop outputting the commands stored in the command queue in response to the notification signal.

The buffer memory 300 may store data only when power is supplied from the power supply. The buffer memory 300 may temporarily store the data from the host. In one embodiment, the buffer memory 300 may, additionally or alternatively, temporarily store the data from the memory device 100.

The buffer memory 300 may be in memory controller 200 or may be outside and coupled to the memory controller 200. The buffer memory may be, for example, a volatile memory, examples of which include a DRAM, SRAM, Double Data Rate Synchronous Dynamic Random Access Memory (DDR SDRAM), Low Power Double Data4 (LPDDR4) SDRAM, Graphics Double Data Rate (GDDR) SDRAM, Low Power DDR (LPDDR), and Rambus Dynamic Random Access Memory (RDRAM).

The buffer memory 300 may include a data buffer 310 and a metadata buffer 320. The data buffer 310 may temporarily store the data from the host 400. In one embodiment, the data buffer 310 may, additionally or alternatively, temporarily store the data from the memory device 100. The data stored in the data buffer 310 may be write data or read data.

The metadata buffer 320 may temporarily store metadata. Additionally or alternatively, the metadata buffer 320 may temporarily store firmware data from the memory device 100 at a predetermined time, e.g., the time of booting or another time.

The host 400 may communicate with the storage device 1000 through an interface. The interface may be, for example, as a serial advanced technology attachment (SATA) interface, a SATA express (SATAe) interface, a serial attached small computer system (SAS) interface, a peripheral component interconnect express (PCIe) interface, a non-volatile memory Express (NVMe) interface, an advanced host controller interface (AHCI), a multimedia card interface or another type of interface.

The host 400 may store data in the storage device 1000 or may communicate with the storage device 1000 to acquire data stored in the storage device 1000.

According to an embodiment, the host 400 may provide the storage device 1000 with a write request to store data in the storage device 1000. In addition, the host 400 may provide the storage device 1000 with the write request, data, and a logical address for identifying the data.

In response to the write request from the host 400, the storage device 1000 may store the write data including the metadata and data provided by the host 400 to the memory device 100, and may provide the host 400 with a response to indicate that the write data has been completely stored in the memory device 100.

According to an embodiment, the host 400 may provide the storage device 1000 with a read request to provide the data stored in the storage device 1000 to the host 400. In addition, the host 400 may provide the read request and a read address to the storage device 1000.

In response to the read request from the host 400, the storage device 1000 may read read data corresponding to the read address provided by the host 400 and may provide the read data in response to the read request to the host 400.

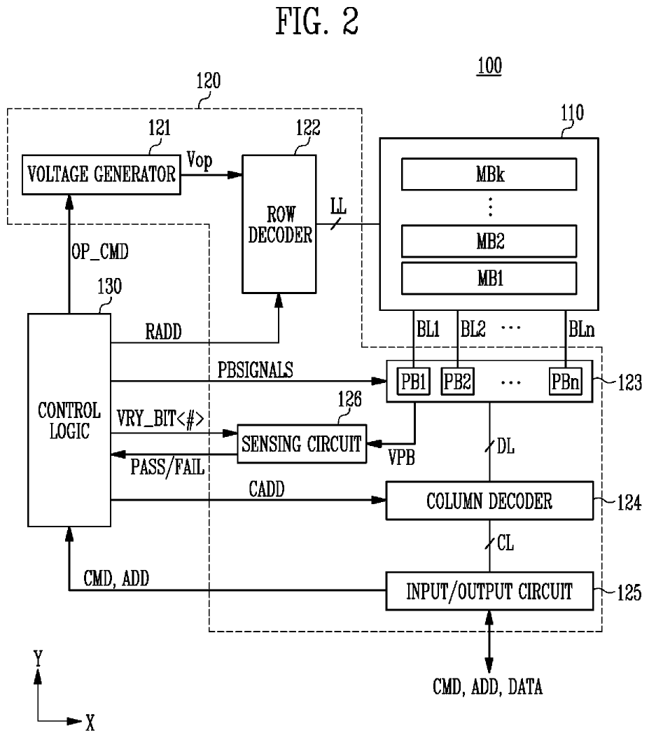

FIG. 2 is a diagram illustrating an embodiment of the memory device 100, which may include a memory cell array 110, a peripheral circuit 120 and a control logic 130.

Referring to FIG. 2, memory cell array 110 may include a plurality of memory blocks MB1 to MBk, where k is a positive integer. Each of the memory blocks MB1 to MBk may be coupled to local lines LL and bit lines BL1 to BLn, where n is a positive integer. The local lines LL may be coupled to a row decoder 122 and to the memory blocks MB1 to MBk, respectively.

The local lines LL may include a first select line, a second select line, and a plurality of word lines arranged between the first select line and the second select line. The local lines LL may further include dummy lines arranged between the first select line and the word lines, dummy lines arranged between the second select line and the word lines, and pipe lines.

The bit lines BL1 to BLn may be commonly coupled to the memory blocks MB1 to MBk.

The memory blocks MB1 to MBk may have a two-dimensional or three-dimensional structure. In a two-dimensional structure, memory cells may be arranged in a direction parallel to a substrate. In a three-dimensional structure, the memory cells may be arranged in a direction vertical to the substrate.

The peripheral circuit 120 may include a voltage generator 121, the row decoder 122, a page buffer group 123, a column decoder 124, an input/output circuit 125, and a sensing circuit 126.

The voltage generator 121 may generate various operating voltages Vop applied for a program operation, a read operation and an erase operation in response to an operation command OP_CMD. In addition, the voltage generating circuit 121 may selectively discharge the local lines LL in response to the operation command OP_CMD. For example, control logic 130 may control the voltage generator 121 to generate a program voltage, a verify voltage, pass voltages, a turn-on voltage, a read voltage, an erase voltage, and a source line voltage.

According to an embodiment, the voltage generator 121 may generate an internal power voltage by regulating an external power voltage. The internal power voltage generated by the voltage generator 121 may serve as an operating voltage of the memory device 100.

According to an embodiment, the voltage generator 121 may generate a plurality of voltages using the external power voltage or the internal power voltage. For example, the voltage generator 121 may include a plurality of pumping capacitors that receive the internal power voltage and generate a plurality of voltages by selectively activating the pumping capacitors in response to the control of the control logic 130. The generated voltages may be supplied to the memory cell array 110 by the row decoder 122.

The row decoder 122 may transfer the operating voltages Vop to the local lines LL in response to a row address RADD. The operating voltages Vop may be transferred to a selected memory block (MB1 to MBk) through the local lines LL.

During a program operation, for example, the row decoder 122 may apply a program voltage to the selected word line and a program pass voltage having a lower voltage level than the program voltage to unselected word lines. During a program verify operation, the row decoder 122 may apply a verify voltage to the selected word line and a verify pass voltage greater than the verify voltage to the unselected word lines.

During a read operation, the row decoder 122 may apply a read voltage to the selected word line and a read pass voltage greater than the read voltage to the unselected word lines.

During an erase operation, the row decoder 122 may select one of the memory blocks according to the decoded address. During the erase operation, the address decoder 122 may apply a ground voltage to word lines coupled to the selected memory block.

The page buffer group 123 may include first to nth page buffers PB1 to PBn coupled to the memory cell array 110 through the first to nth bit lines BL1 to BLn, respectively. The first to nth page buffers PB1 to PBn may operate in response to the control of the control logic 130.

In one embodiment, the first to nth page buffers PB1 to PBn may operate in response to page buffer control signals PBSIGNALS. For example, the first to nth page buffers PB1 to PBn may temporarily store data received through the first to nth bit lines BL1 to BLn, respectively, or may sense voltages or currents in the first to nth bit lines BL1 to BLn during a read operation or a verify operation.

During a program operation, when a program voltage is applied to a selected word line, the first to nth page buffers PB1 to PBn may transfer data DATA, received through the column decoder 124 and the input/output circuit 125, to selected memory cells through the first to nth bit lines BL1 to BLn, respectively. The memory cells of the selected page may be programmed according to the transferred data DATA. A memory cell coupled to a bit line to which a program permission voltage (e.g., a ground voltage) is applied may have an increased threshold voltage. A threshold voltage of a memory cell coupled to a bit line, to which a program inhibition voltage (for example, a power voltage) is applied, may be maintained.

During a verify operation, the first to nth page buffers PB1 to PBn may sense data stored in the selected memory cells through the first to nth bit lines BL1 to BLn, respectively.

During a read operation, the first to nth page buffers PB1 to PBn may sense the data DATA from the memory cells of the selected page through the first to nth bit lines BL1 to BLn, respectively, and may output the sensed data DATA to the input/output circuit 125 in response to control of the column decoder 124.

During an erase operation, the first to nth page buffers PB1 to PBn may float the first to nth bit lines BL1 to BLn, respectively.

The column decoder 124 may transfer data between the input/output circuit 125 and the page buffer group 123 in response to a column address CADD. For example, the column decoder 124 may exchange data with the first to nth page buffers PB1 to PBn through data lines DL, or may exchange data with the input/output circuit 125 through column lines CL.

The input/output circuit 125 may transfer a command CMD and an address ADDR from the memory controller 200 to the control logic 130, or may exchange the data DATA with the column decoder 124.

The sensing circuit 126 may generate a reference current in response to an allowable bit VRY_BIT<#> and compare a sensing voltage VPB from the page buffer group 123 with a reference voltage generated by the reference current to output a pass signal PASS or a fail signal FAIL during a read operation or a verify operation.

The control logic 130 may control the peripheral circuit 120 by outputting the operation command OP_CMD, the row address RADD, the page buffer control signals PBSIGNALS and the allowable bit VRY_BIT<#> in response to the command CMD and the address ADD.

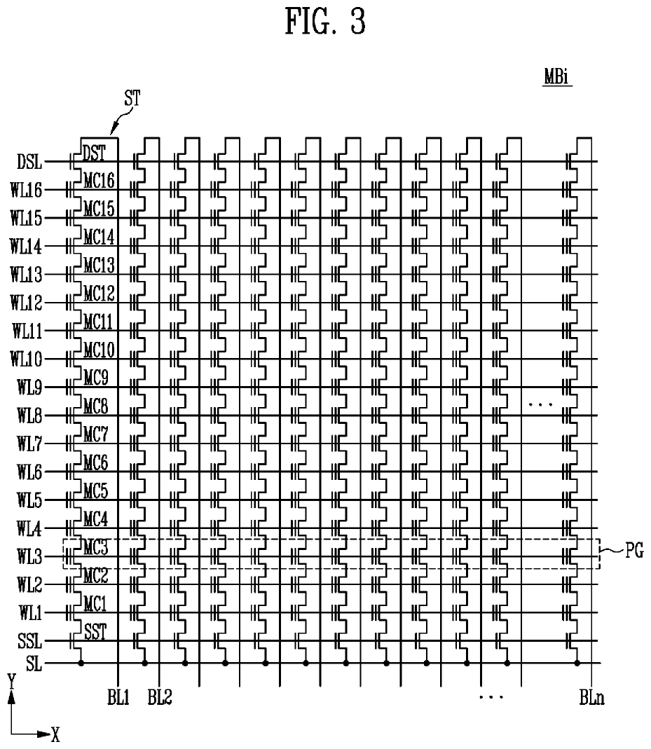

FIG. 3 is a diagram illustrating an embodiment of a memory block MBi, which, for example, may be representative of the memory blocks MB1 to MBk shown in FIG. 2.

The memory block MBi may include a first select line, a second select line, a plurality of word lines WL1 to WL16, a source line SL, a plurality of bit lines BL1 to BLn, and a plurality of strings ST. The first select line may be, for example, a source select line SSL. Hereinafter, the first select line may be assumed as the source select line SSL. The first select line may be, for example, a drain select line DSL. Hereinafter, the second select line may be assumed as the drain select line DSL.

The word lines WL1 to WL16 may be arranged in parallel with each other between the source select line SSL and the drain select line DSL. The number of word lines WL1 to WL16 as shown in FIG. 3 is an illustrative example and may be a different number in another embodiment.

The source line SL may be coupled in common to a plurality of strings ST.

The bit lines BL1 to BLn may be coupled to the strings ST, respectively.

The strings ST may be coupled between the bit lines BL1 to BLn and the source line SL and, for example, may have the same configuration. A string ST coupled to the first bit line BL1 will be described as an example.

The string ST may include a plurality of memory cells MC1 to MC16, at least one select transistor, and at least one second select transistor. The memory cells MC1 to MC16 may be coupled in series between a source select transistor SST and a drain select transistor DST. Gate electrodes of the memory cells MC1 to MC16 may be coupled to the plurality of word lines WL1 to WL16, respectively. Therefore, the number of memory cells MC1 to MC16 in one string ST may be the same as the number of word lines WL1 to WL16.

Each of the memory cells MC1 to MC16 may be a single level cell (SLC) that stores 1 bit of data, a multi-level cell (MLC) that stores 2 bits of data, a triple-level cell (TLC) that stores 3 bits of data, a quadruple level cell (QLC) that stores 4 bits of data, or a memory cell that stores 5 or more bits of data.

A group of memory cells coupled to the same word line, among the memory cells in the different strings ST, may be referred to as a physical page PG. Therefore, the memory block MBi may include as many physical pages PG as the number of word lines WL1 to WL16. Hereinafter, memory cells (e.g., MC3) in the physical page PG are selected memory cells.

The first select transistor may be, for example, the source select transistor SST. Hereinafter, the first select transistor may be assumed as the source select transistor SST. A first electrode of the source select transistor SST may be coupled to the source line SL. A second electrode of the source select transistor SST may be coupled to the first memory cell MC1 among the memory cells MC1 to MC16. A gate electrode of the source select transistor SST may be coupled to the source select line SSL.

The second select transistor may be, for example, the drain select transistor DST. Hereinafter, the second select transistor may be assumed as the drain select transistor DST. A first electrode of the drain select transistor DST may be coupled to the 16th memory cell MC16 among the memory cells MC1 to MC16. A second electrode of the drain select transistor DST may be coupled to the first bit line BL1. A gate electrode of the drain select transistor DST may be coupled to the drain select line DSL.

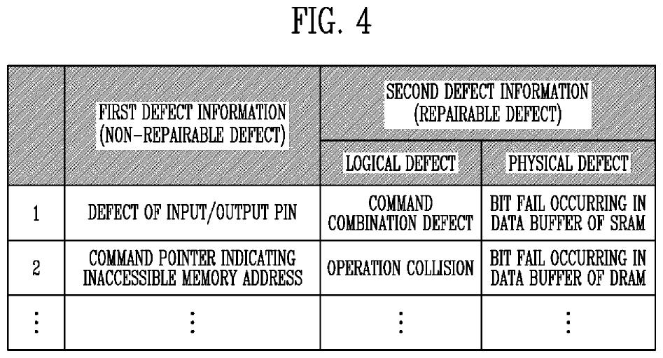

FIG. 4 is a diagram illustrating of defect information according to an embodiment. The defect information may be included in a table stored in defect information storage 210, for example, as described with reference to FIG. 1. The defect information table may include defect information, which, for example, is generated beforehand through experiment, design, manufacturer requirements, testing or through other methods. In addition, the defect information may be stored before the storage device 1000 is released.

According to an embodiment, the defect information may include first defect information corresponding to a non-repairable defect and second defect information corresponding to a repairable defect.

A non-repairable defect in the first defect information may include, for example, a defect in an input/output pin, an error of a command pointer (or a program counter) that indicates an inaccessible memory address, and/or another type of defect. Except for replacement of a physical configuration due to damaged hardware, a non-repairable defect may correspond to the first defect information.

The second defect information may include information corresponding to a logical defect that occurs in firmware (or other instructions) in the memory controller 200. The logical defect may include, for example, a command combination defect that refers to an error in a combination of commands which cannot be provided at the same time to the memory device 100, an operation collision that refers to a hang condition where the storage device 1000 temporarily stops operating due to collision between operations for controlling the memory device 100 at an unexpected time, an unexpected operation performed due to an error in a function pointer of the firmware (or instructions), and/or another type of defect. A phenomenon that the storage device 1000 temporarily stops working due to the collision between the operations may be referred to as a deadlock.

The second defect information may include information corresponding to a physical defect in the buffer memory 300. The physical defect may be, for example, a bit fail that occurs in a data buffer of SRAM when the buffer memory 300 corresponds to the SRAM in the memory controller 200. When the buffer memory 300 is a DRAM in the memory device 100, the physical defect may be a bit fail that occurs in a data buffer of the DRAM. The physical defect may, additionally or alternatively, include other types of defects in other embodiments.

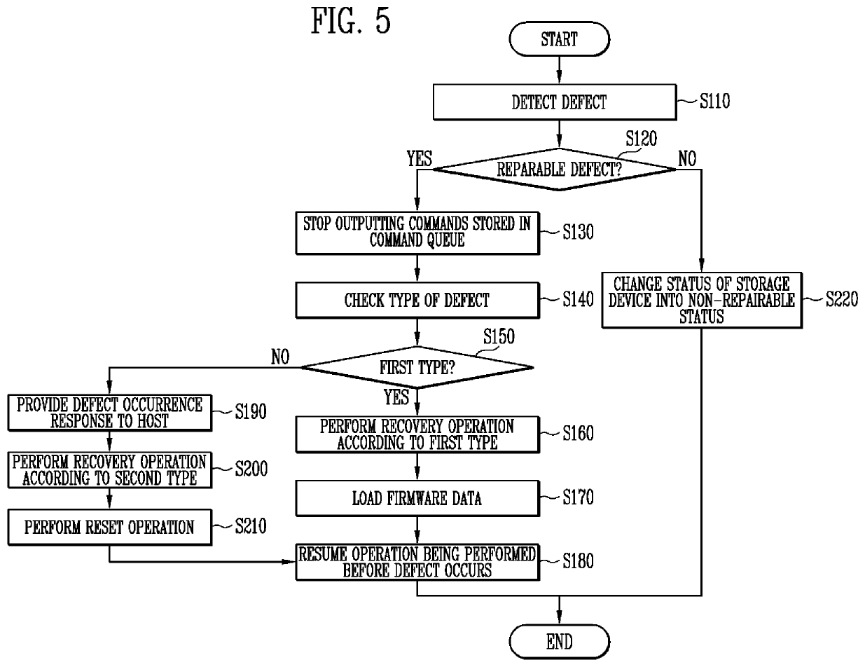

FIG. 5 is a flowchart illustrating an embodiment of a method of performing a recovery operation according to a type of a defect.

Referring to FIG. 5, the method includes, at S110, the memory controller 200 detecting a defect.

At S120, the memory controller 200 determines whether the detected defect is repairable or non-repairable.

At S130, when the detected error is determined to be repairable (S120, Yes), the memory controller 200 may stop outputting commands stored in the command queue.

At S140, the memory controller 200 may proceed to check a type of the detected defect.

At S150, the memory controller 200 may check whether or not the type of the detected defect is a first type.

At S160, when the type of the detected defect is the first type (S150, Yes), the memory controller 200 may perform a recovery operation according to the first type.

At S170, when the recovery operation according to the first type is completed, the memory controller 200 may load firmware data stored in the memory device 100. For example, when the type of the detected defect is the first type, the recovery operation performer 230 may control the memory device 100 to acquire the firmware data stored in the memory device 100 before an operation being performed prior to the occurrence of the defect is resumed.

At S180, the memory controller 200 may resume the operation being performed before the defect occurred. For example, when the type of the detected defect is the first type, the recovery operation performer 230 may output a control signal to indicate that the operation performed before the defect occurred is to be resumed after the recovery operation is completed. The operation controller 240 may resume the operation being performed before the defect occurs in response to the control signal.

At S190, when the type of the detected defect is not the first type (e.g., when the type of the detected defect is a second type at S150, No), the memory controller 200 may provide a defect occurrence response to the host 400. For example, when the type of the detected defect is the second type, the recovery operation performer 230 may provide the host 400 with the defect occurrence response to indicate that the defect has occurred before the recovery operation is performed.

At S200, the memory controller 200 may perform a recovery operation according to the second type.

At S210, the memory controller 200 may perform a reset operation, which, for example, may include rebooting in response to an externally provided rebooting command, self-rebooting, or waiting until the external power supply is blocked.

The recovery operation performer 230 may wait until the external power supply is blocked after the recovery operation is completed. For example, the recovery operation performer 230 may provide the host 400 with a rebooting response to indicate that a rebooting command is to be provided after the recovery operation is completed. In addition, the recovery operation performer 230 may wait until the memory controller 200 receives the rebooting command since the rebooting response is provided to the host 400. In addition, the recovery operation performer 230 may perform rebooting in response to the rebooting command provided from the host 400.

In one embodiment, the recovery operation performer 230 may self-reboot after the recovery operation is completed.

After the reset operation is completed, operation S180 may be performed. For example, when the power is supplied again after interruption, the recovery operation performer 230 may output to the operation controller 240, a control signal to indicate that an operation being performed before the defect occurred is to be resumed. The operation controller 240 may resume the operation being performed before the defect occurred in response to the control signal.

At the time of rebooting, the recovery operation performer 230 may load firmware data stored in the memory device 100.

At S220, when the detected defect is determined to be non-repairable (S120, No), the memory controller 200 may change a status of the storage device 1000 into a non-repairable status.

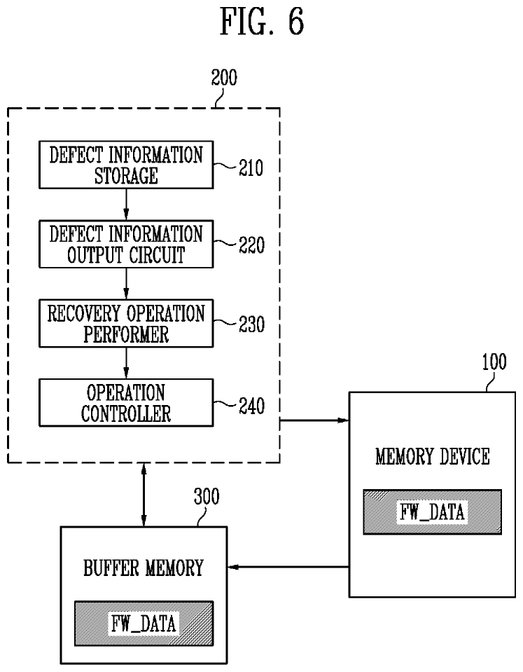

FIG. 6 is a diagram illustrating an embodiment of a method of loading firmware data. In this embodiment, the defect information output circuit 220 may detect a defect and output defect information corresponding to the detected defect using the defect information table stored in defect information storage 210.

The recovery operation performer 230 may determine whether the detected defect is repairable or non-repairable based on defect information provided from the defect information output circuit 220. When the detected defect is repairable, the recovery operation performer 230 may perform a recovery operation according to a type of the detected defect.

When the recovery operation is completed, the recovery operation performer 230 may control the memory device 100 to read firmware data FW_DATA. The firmware data FW_DATA may be stored in the system block 102, for example, as described with reference to FIG. 1. The memory device 100 may perform a read operation for reading the firmware data FW_DATA and may output the read firmware data FW_DATA.

The recovery operation performer 230 may load the read firmware data FW_DATA onto the buffer memory 300. The loaded firmware data FW_DATA may be temporarily stored in the metadata buffer 320, for example, as described above with reference to FIG. 1. The recovery operation performer 230 may output the control signal to the operation controller 240 as described above.

The operation controller 240 may execute firmware based on the firmware data FW_DATA temporarily stored in the buffer memory 300. The operation controller 240 may perform an operation that was being performed before the defect occurred in response to the control signal from the recovery operation performer 230.

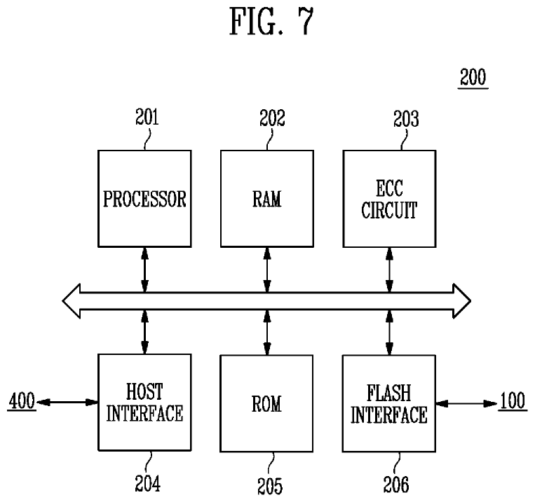

FIG. 7 is a diagram illustrating an embodiment of a memory controller 200, which may include a processor 201, a RAM 202, an error correction circuit 203, a host interface 204, a ROM 205, and a flash interface 206.

The processor 201 may control the overall operation of the memory controller 200.

The RAM 202 may serve as a buffer memory, a cache memory, or a working memory of the memory controller 200. For example, the RAM 202 may be the buffer memory.

The error correction circuit 203 may generate an error correction code (ECC) to correct a fail bit or an error bit of the data received from the memory device 100. For example, the error correction circuit 203 may perform error correction encoding on data provided to the memory device 100, in order to generate data to which one or more parity bits are added. The one or more parity bits may be stored in the memory device 100.

Additionally, the error correction circuit 203 may perform error correction decoding on the data output from the memory device 100. The error correction circuit 203 may correct an error using the parity. For example, the error correction circuit 203 may correct errors using one or more coded modulation schemes. Code examples include low density parity check (LDPC) code, BCH code, turbo code, Reed-Solomon code, convolutional code, recursive systematic code (RSC), TCM, and BCM.

The error correction circuit 203 may calculate an error correction code value of data to be programmed into the memory device 100 during a program operation. The error correction circuit 203 may perform an error correction operation on the data read from the memory device 100 during a read operation based on the error correction code value. The error correction circuit 203 may perform an error correction operation on the data recovered from the memory device 100 by a recovery operation of failed data.

The memory controller 200 may communicate with an external device (e.g., the host 400, an application processor, etc.) through a host interface 204.

The ROM 205 may store various kinds of information in the form of firmware (or instructions) which is to be used by the memory controller 200 to operate.

The memory controller 200 may communicate with the memory device 100 through an interface 206, e.g., a flash interface. The memory controller 200 may transfer the command CMD, the address ADDR and the control signal CTRL to the memory device 100 or may receive data through the flash interface 206. The flash interface 206 may include, for example, a NAND interface.

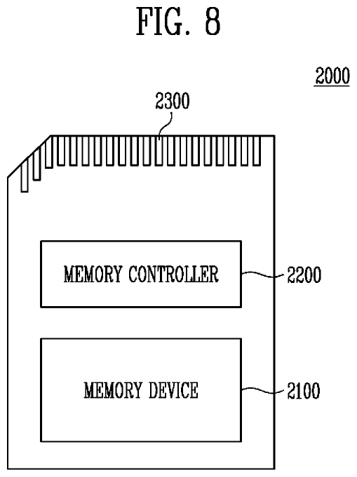

FIG. 8 is a block diagram illustrating an embodiment of a memory card system 2000 to which a storage device according to any of the embodiment described herein may be applied.

Referring to FIG. 8, the memory card system 2000 may include a memory device 2100, a memory controller 2200, and a connector 2300. In an embodiment, the memory device 2100 may be implemented as any of various nonvolatile memory devices/. Examples include an Electrically Erasable and Programmable ROM (EEPROM), a NAND flash memory, a NOR flash memory, a Phase-change RAM (PRAM), a Resistive RAM (ReRAM), a Ferroelectric RAM (FRAM), a Spin-Torque Magnetic RAM (STT-MRAM).

The memory controller 2200 may be coupled to and access the memory device 2100. The memory controller 2200 may control read, write, erase, and background operations of the memory device 2100. The memory controller 2200 may be configured to serve as an interface between the memory device 2100 and the host. The memory controller 2200 may be configured to drive firmware (or other types of instructions) for controlling the memory device 2100. The memory controller 2200 may have the same configuration, for example, as the memory controller 200 described with reference to FIG. 1.

In an embodiment, the memory controller 2200 may include components such as a Random Access Memory (RAM), a processing unit, a host interface, a flash interface, and/or an ECC circuit. The memory controller 2200 may communicate with an external device through the connector 2300 and may communicate with an external device (e.g., host) based on a communication protocol. Examples of the communication protocol include a universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe) protocols. In an embodiment, the connector 2300 may be defined by at least one of the above-described various communication protocols.

The memory device 2100 and the memory controller 2200 may be integrated into a single semiconductor device to form a memory card. Examples of the memory card include a personal computer memory card international association (PCMCIA), a compact flash card (CF), a smart media card (SM or SMC), a memory stick multimedia card (MMC, RS-MMC, or MMCmicro), a SD card (SD, miniSD, microSD, or SDHC), a universal flash storage (UFS), and the like.

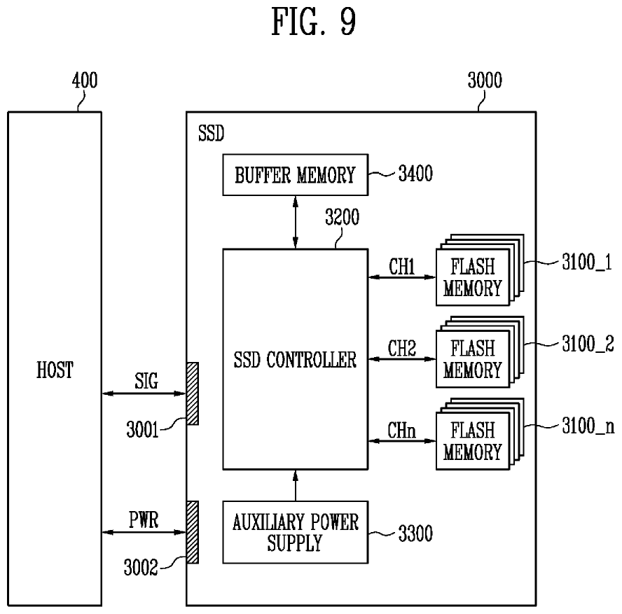

FIG. 9 is a block diagram illustrating an embodiment of a solid state drive (SSD) system to which a storage device according to any embodiment of the embodiments described herein may be applied.

Referring to FIG. 9, an SSD system may include the host 400 and an SSD 3000. The SSD 3000 may exchange signals SIG with the host 400 through a signal connector 3001 and may receive power PWR through a power connector 3002. The SSD 3000 may include an SSD controller 3200, a plurality of flash memories 3100_1, 3100_2, and 3100_n, an auxiliary power supply 3300, and a buffer memory 3400.

In an embodiment, the SSD controller 3200 may perform the function of the memory controller 200, for example, as described with reference to FIG. 1.

The SSD controller 3200 may control the flash memories 3100_1, 3100_2, and 3100_n in response to signals SIG received from the host 400. In an embodiment, the signals SIG may be based on the interfaces of the host 400 and the SSD 3000. For example, the signals SIG may correspond to at least one of various interfaces. Example interfaces include universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe) interfaces.

The auxiliary power supply 3300 may be coupled to the host 400 through the power connector 3002. The auxiliary power supply 3300 may be supplied and charged with the power PWR from the host 400. The auxiliary power supply 3300 may supply the power of the SSD 3000 when power is not supplied smoothly (or according to a predetermined level or pattern) from the host 400. In an embodiment, the auxiliary power supply 3300 may be inside or outside and coupled to the SSD 3000. For example, the auxiliary power supply 3300 may be in a main board and may supply auxiliary power to the SSD 3000.

The buffer memory 3400 may temporarily store data, for example, received from the host 400 and/or data received from the flash memories 3100_1, 3100_2, and 3100_n. Additionally or alternatively, the buffer memory 3400 may temporarily store metadata (e.g., mapping tables) of the flash memories 3100_1, 3100_2, and 3100_n. The buffer memory 3400 may include one or more volatile memories (e.g., DRAM, SDRAM, DDR SDRAM, LPDDR SDRAM, GRAM, etc.) and/or one or more nonvolatile memories (e.g., FRAM, ReRAM, STT-MRAM, PRAM, etc.).

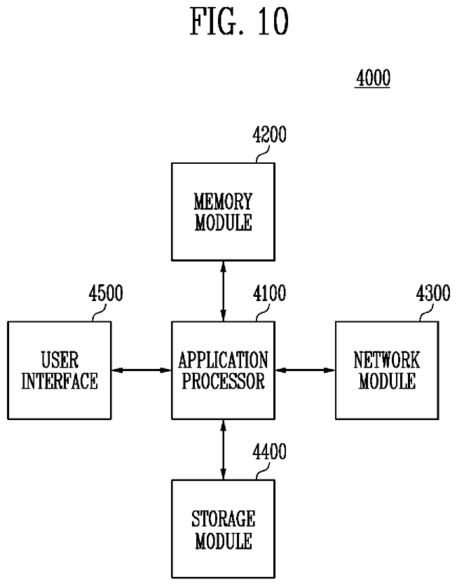

FIG. 10 is a block diagram illustrating an embodiment of a user system 4000 to which a storage device according to any of the embodiments described herein may be applied.

Referring to FIG. 10, the user system 4000 may include an application processor 4100, a memory module 4200, a network module 4300, a storage module 4400, and a user interface 4500.

The application processor 4100 may run components in the user system 4000, an Operating System (OS), and/or a user program. In an embodiment, the application processor 4100 may include controllers, interfaces, graphic engines, etc., for controlling the components in the user system 4000. In one embodiment, the application processor 4100 may be provided as a system-on-chip (SoC).

The memory module 4200 may function as a main memory, a working memory, a buffer memory or a cache memory of the user system 4000. The memory module 4200 may include one or more volatile RAMs (e.g., DRAM, SDRAM, DDR SDRAM, DDR2 SDRAM, DDR3 SDRAM, LPDDR SDARM, LPDDR2 SDRAM, LPDDR3 SDRAM, etc.) and/or one or more nonvolatile RAMs (e.g., PRAM, ReRAM, MRAM, FRAM, etc.). In an embodiment, the application processor 4100 and the memory module 4200 may be packaged based on package-on-package (POP) and may then be provided as a single semiconductor package.

The network module 4300 may communicate with external devices. For example, the network module 4300 may support wireless communication, such as Code Division Multiple Access (CDMA), Global System for Mobile communication (GSM), wideband CDMA (WCDMA), CDMA-2000, Time Division Multiple Access (TDMA), Long Term Evolution (LTE), Wimax, WLAN, UWB, Bluetooth, or WiFi communication. In an embodiment, the network module 4300 may be included in the application processor 4100.

The storage module 4400 may store data, for example, received from the application processor 4100. In one embodiment, the storage module 4400 may transmit the data stored in the storage module 4400 to the application processor 4100. In an embodiment, the storage module 4400 may be implemented as a nonvolatile semiconductor memory device. Examples include a Phase-change RAM (PRAM), a Magnetic RAM (MRAM), a Resistive RAM (RRAM), a NAND flash memory, a NOR flash memory, or a NAND flash memory having a three-dimensional (3D) structure. In an embodiment, the storage module 4400 may be provided as a removable storage medium (e.g., removable drive) such as a memory card or an external drive of the user system 4000.

For example, the storage module 4400 may include a plurality of non-volatile memory devices that operate, for example, in the same manner as the memory device 100 described with reference to FIG. 1. The non-volatile memory devices may operate, for example, in the same manner as the storage device 1000 as described with reference to FIG. 1.

The user interface 4500 may include interfaces which input data or commands to the application processor 4100 or output data to an external device. In an embodiment, the user interface 4500 may include one or more user input interfaces (e.g., keyboard, keypad, button, touch panel, touch screen, touch pad, touch ball, camera, microphone, gyroscope sensor, vibration sensor, piezoelectric device, etc.) and/or one or more user output interfaces (e.g., Liquid Crystal Display (LCD), Organic Light Emitting Diode (OLED) display device, Active Matrix OLED (AMOLED) display device, LED, speaker, motor, etc.).

In accordance with one embodiment, an apparatus includes a storage configured to store instructions and logic configured to execute the instructions to perform any of the embodiments described herein. For example, the logic may be configured to detect a defect occurring in at least one of a memory controller or a buffer memory, check whether or not the defect is reparable based on information in a defect information table, and perform a recovery operation based on a type of the defect when the defect is reparable. The logic may correspond, for example, to the memory controller as described herein.

According to one or more of the aforementioned embodiments, a memory controller having improved reliability and a storage device including such a memory controller are provided.

The methods, processes, and/or operations described herein may be performed by code or instructions to be executed by a computer, processor, controller, or other signal processing device. The computer, processor, controller, or other signal processing device may be those described herein or one in addition to the elements described herein. Because the algorithms that form based on the methods (or operations of the computer, processor, controller, or other signal processing device) are described, the code or instructions for implementing the operations of the method embodiments may transform the computer, processor, controller, or other signal processing device into a special-purpose processor to perform the methods herein.

When implemented in at least partially in software, the controllers, processors, devices, modules, performers, units, multiplexers, generators, logic, interfaces, decoders, drivers, generators and other signal generating and signal processing features may include, for example, a memory or other storage device for storing code or instructions to be executed, for example, by a computer, processor, microprocessor, controller, or other signal processing device. The computer, processor, microprocessor, controller, or other signal processing device may be those described herein or one in addition to the elements described herein. Because the algorithms that form the basis of the methods (or operations of the computer, processor, microprocessor, controller, or other signal processing device) are described in detail, the code or instructions for implementing the operations of the method embodiments may transform the computer, processor, controller, or other signal processing device into a special-purpose processor for performing the methods described herein.

In the above-discussed embodiments, all steps may be selectively performed or skipped. In addition, the steps in each embodiment may not always be performed in regular order. Furthermore, the embodiments disclosed in the present specification and the drawings aims to help those with ordinary knowledge in this art more clearly understand the present disclosure rather than aiming to limit the bounds of the present disclosure. In other words, one of ordinary skill in the art to which the present disclosure belongs will be able to easily understand that various modifications are possible based on the technical scope of the present disclosure. It will be apparent to those skilled in the art that various modifications can be made to the above-described exemplary embodiments of the present disclosure without departing from the spirit or scope of the invention. Thus, it is intended that the present disclosure cover all such modifications provided they come within the scope of the appended claims and their equivalents.

What is claimed is:

1. A memory controller, comprising:
a storage configured to store first defect information corresponding to a non-repairable defect and second defect information corresponding to a repairable defect;
an output circuit configured to detect a defect in the memory controller and to output the first or second defect information as defect information corresponding to a detected defect; and
logic configured to check a type of the detected defect based on the second defect information when the defect information corresponds to the second defect information and to perform a recovery operation according to the type of the detected defect.

2. The memory controller of claim 1, wherein the logic is configured to output a control signal to indicate that an operation that was being performed before the defect occurred is to be resumed, after the recovery operation is completed.

3. The memory controller of claim 2, wherein
when the type of the detected defect is a first type, the logic is configured to control the memory device to acquire firmware data stored in the memory device before the operation, performed prior to occurrence of the defect, is resumed.

4. The memory controller of claim 2, wherein
when the type of the detected defect is a second type, the logic is configured to wait until power being supplied externally is blocked, after the recovery operation is completed.

5. The memory controller of claim 4, wherein the logic is configured to output a control signal to indicate that the operation that was being performed before the defect occurred, is to be resumed when the power is supplied again after being blocked.

6. The memory controller of claim 2, wherein
when the type of the detected defect is a second type, the logic is configured to provide a host with a rebooting response to indicate that a rebooting command is to be provided, after the recovery operation is completed.

7. The memory controller of claim 6, wherein the logic is configured to wait until the rebooting command is provided to the memory controller since the rebooting response is provided to the host.

8. The memory controller of claim 2, wherein
when the type of the detected defect is a second type, the logic is configured to perform a reboot after the recovery operation is completed.

9. The memory controller of claim 2, wherein
when the type of the detected defect is a second type, the logic is configured to provide a host with a defect occurrence response providing notification that the defect occurred before performing the recovery operation.

10. The memory controller of claim 1, wherein the second defect information includes
information indicating a logical defect occurring in firmware in the memory controller, and
information indicating a physical defect occurring in a buffer memory in the memory controller.

11. The memory controller of claim 1, further comprising
an operation controller configured to store a command to perform an operation corresponding to the request in a command queue, and to provide commands stored in the command queue to the memory device,
wherein the logic is configured to provide a notification signal to the operation controller to stop outputting the commands stored in the command queue when the recovery operation starts.

12. A storage device, comprising:
a memory device including a plurality of memory blocks;
a buffer memory configured to temporarily store data from a host or the memory device; and
a memory controller configured to control the memory device to perform an operation corresponding to a request from the host, wherein the memory controller is configured to:
detect a defect occurring in the memory controller or the buffer memory,
check whether or not the defect is reparable based on information in a defect information table, and
perform a recovery operation according to a type of the defect when the defect is reparable.

13. The storage device of claim 12, wherein
the defect information table includes first defect information corresponding to a non-repairable defect and second defect information corresponding to a repairable defect, and
the second defect information indicates a logical defect occurring in firmware in the memory controller and a physical defect occurring in the buffer memory.

14. The storage device of claim 12, wherein the memory controller is configured to resume an operation that was being performed before the defect occurred, after the recovery operation is completed.

15. The storage device of claim 14, wherein
when the type of the detected defect is a second type, the memory controller is configured to wait until power being supplied externally to the storage device is blocked, after the recovery operation is completed.

16. The storage device of claim 15, wherein the memory controller is configured to resume the operation that was being performed before the defect occurred when the power is supplied again after being blocked.

17. The storage device of claim 14, wherein
when the type of the detected defect is a second type, the memory controller is configured to provide the host with a rebooting response to indicate that a rebooting command is to be provided, after the recovery operation is completed.

18. The storage device of claim 17, wherein the memory controller is configured to wait until the rebooting command is provided to the memory controller since the rebooting response is provided to the host.

19. The storage device of claim 14, wherein
when the type of the detected defect is a second type, the memory controller is configured to perform a reboot operation after the recovery operation is completed.

20. The storage device of claim 14, wherein
when the type of the detected defect is a second type, the memory controller is configured to provide the host with a defect occurrence response to indicate that the defect occurred, before the recovery operation is performed.
